(19) United States
(12) Patent Application Publication
(10) Pub. No.: US 2012/0204930 A1
(43) Pub. Date: Aug. 16, 2012

(54) THIN-LAYER SOLAR MODULE HAVING IMPROVED INTERCONNECTION OF SOLAR CELLS AND METHOD FOR THE PRODUCTION THEREOF

(75) Inventor: Victor Verdugo, Dresden (DE)

(73) Assignee: Q-CELLS SE, Bitterfeld-Wolfen (DE)

(21) Appl. No.: 13/384,987

(22) PCT Filed: Jul. 20, 2010
(86) PCT No.: PCT/EP2010/060481

§ 371 Date: May 2, 2012

(30) Foreign Application Priority Data
Jul. 20, 2009 (DE) 10 2009 027 852.4

(51) Int. Cl. H01L 31/042; H01L 31/18

(52) U.S. Cl. 136/244; 438/73; 257/E31.037

(57) ABSTRACT

A thin-layer solar module includes a plurality of interconnected solar cells, having in the order indicated the layers (a) a substrate 3; (b) a first electrode layer 4; (c) a semiconductor layer 5; and (d) a second electrode layer 6. At least one non-linear recess is disposed in the first electrode layer and a second non-linear recess is disposed in the second electrode layer and in the semiconductor layer, wherein a first projection of the first non-linear recess onto the substrate 3 and a second projection 10 of the second non-linear recess onto the substrate intersect or contact each other at least two projection points. The thin-layer solar module has at least one island-shaped contact region extending in a direction vertical to the substrate through the layers (a) through (d). A third recess is present in the semiconductor layer 5 within the island-shaped contact region 11 and is filled with an electrically conductive material.

### CROSS REFERENCE TO RELATED APPLICATIONS

This application is a 371 National Stage filing of PCT International Application No. PCT/EP2010/060481, filed on Jul. 20, 2010, and published in German on Jan. 27, 2011 as WO 2011/009860 A2, which claims priority to German Patent Application No. DE 10 2009 027 852.4, filed on Jul. 20, 2009, the entire disclosures of which are incorporated herein by reference.

### FIELD OF THE INVENTION

The invention relates to a thin-film solar module with improved interconnection of solar cells, and to a method for its production. In particular, the invention relates to a thin-film solar module which contains a plurality of interconnected solar cells, with the thin-film solar module or the solar cell comprising a substrate, a first electrode layer, a semiconductor layer and a second electrode layer.

### BACKGROUND OF THE INVENTION

The widespread use of solar modules, which convert solar energy directly to electrical energy, has increased very greatly in recent years. In a solar module which contains individual series-connected or parallel-connected solar cells, the separation of charge carriers, which is achieved by the influence of the sunlight on a semiconductor material in a semiconductor layer therein, and their subsequently being carried away, is achieved by electrodes which are arranged on the semiconductor material. In this case, the amount of semiconductive material used in the semiconductor layer has until now been relatively large. However, this leads to problems in the provision of adequate amounts of sufficiently pure semiconductor material, and to comparatively high costs because of the use of large amounts of semiconductor material.

Work has therefore been increasingly directed at the development of so-called thin-film solar modules, in which the semiconductive layer is comparatively thin. This layer is composed, for example, of amorphous silicon. Because little material is required, such thin-film solar modules are comparatively cheap. One problem when using thin-film solar modules is that the energy efficiency has until now not yet been sufficient, that is to say the incident solar radiation is inadequately utilized.

EP 0 749 161 B1 discloses an integrated thin-film solar battery which has a plurality of series-connected element units, having: a substrate; a plurality of first electrode layers composed of transparent conductive oxide, which are subdivided into a plurality of areas and are formed on the substrate; a plurality of laminates each having one semiconductor layer and a first electrically conductive layer, which is laminated onto the semiconductor layer and is composed of a transparent metal-oxide material, which are arranged on the first electrode layers such that each of the laminates is formed on two adjacent first electrodes and has a connection opening on one of the two first electrodes, with the first electrically conductive layer not being formed in the connection opening; and second electrode layers composed of metallic material, which are arranged on each of the laminates in a state in which the second electrode layers are electrically connected to one of the two first electrode layers through the connection opening, in order to form an area, which is inserted between the second electrode layer and the other first electrode layer, as an element unit.

In these known solar modules, the area which cannot be used for utilization of incident solar radiation (“dead area”) is relatively large.

Against this background, the object of the present invention was to provide a solar module which allows the incident solar radiation to be utilized more efficiently.

According to this invention, this object is achieved by a thin-film solar module and by a method for production of a thin-film solar module having the features of the corresponding independent patent claims. Preferred embodiments of the thin-film solar module according to the invention are specified in appropriate dependent patent claims. Preferred embodiments of the thin-film solar module according to the invention correspond to preferred embodiments of the method according to the invention, and vice versa, even if this is not explicitly mentioned in this document.

### SUMMARY OF THE INVENTION

The subject matter of the invention is therefore a thin-film solar module which contains a plurality of interconnected solar cells, comprising the following layers in the stated sequence:

(a) a substrate;

(b) a first electrode layer;

(c) a semiconductor layer; and

(d) a second electrode layer;

wherein at least one first non-linear recess is arranged in the first electrode layer, and a second non-linear recess is arranged in the second electrode layer and in the semiconductor layer, with a first projection of the first non-linear recess onto the substrate and a second projection of the second non-linear recess onto the substrate intersecting or touching at least two projection points,

the thin-film solar module has at least one contact area which is in the form of an island, extends over the layers (a) to (d) in a direction which is vertical with respect to the substrate and is bounded in a direction parallel to the substrate by the first projection and the second projection, and with a third recess being located in the semiconductor layer within the contact area which is in the form of an island, which third recess is filled with an electrically conductive material, and

with a fourth recess extending through the first electrode layer, the semiconductor layer and the second electrode layer between at least two contact areas which are in the form of islands.

The expression “thin-film solar module”, as it is used in this document, means in particular a thin-film solar module in which a semiconductor layer is thinner than the substrate.

In the thin-film solar module, the first projection and the second projection may jointly have a plurality of points or sections. However, the first projection and the second projection preferably intersect or touch at two and only two projection points in the thin-film solar module according to the invention.

The first non-linear recess and the second non-linear recess may have different shapes. By way of example, the first non-linear recess and/or the second non-linear recess may consist of two linear areas which intersect or touch at one recess intersection point. However, it is also possible for the first and the second non-linear recesses to consist of one or more curves with a standard radius of curvature, or a radius of curvature which varies along the curve. Furthermore, any desired combinations of linear and curved sections are possible for the first non-linear recess and for the second non-linear recess. The contact areas which are in the form of islands, in particular their projections onto the substrate, may therefore have widely differing shapes.

In one preferred embodiment of the thin-film solar module according to the invention, the first non-linear recess and/or the second non-linear recess consist/consists of two linear areas which intersect or touch at a recess intersection point.

The area of the contact area, which is in the form of an island, in the thin-film solar module is, according to the invention, not limited. In general, the contact area has an area in the range from 0.01 to 3 mm² in a direction parallel to the substrate.

The fourth recess is preferably arranged between two projection points of adjacent contact areas which are in the form of islands. In particular, in this case the fourth recess extends in the direction of the connection line of two projection points of the same contact area which is in the form of an island.

In one preferred embodiment of the thin-film solar module, a plurality of fourth recesses are arranged parallel to one another.

Preferably, the fourth recess is linear. This means in particular that a projection of the fourth recess onto the substrate represents a straight line.

It is furthermore preferable for the fourth recess to connect the projection points of two adjacent contact areas which are in the form of islands.

In a further preferred embodiment of the thin-film solar module according to the invention, a third electrically conductive layer, which is different from the second electrode layer, is arranged between the semiconductor layer and the second electrode layer.

The material of the third electrically conductive layer is preferably a transparent electrically conductive material which consists of a metal-oxide material, for example SnO₂, ZnO or ITO. A laminate composed of these materials may likewise be used.

The first electrode layer and the second electrode layer may be formed from the same or different electrically conductive materials. The choice of the electrically conductive materials is not restricted; it is possible to use both inorganic materials, in particular metals, as well as organic materials, in particular electrically conductive polymers. Preferably, at least the first electrode layer is transparent.

In preferred embodiments of the thin-film solar module according to the invention, tin oxide (SnO₂), zinc oxide (ZnO) or indium-tin-oxide (ITO) is suitable for use as a transparent electrically conductive material for the first and/or second electrode layer.

By way of example, aluminum (Al), silver (Ag) or chromium (Cr) is suitable for use as a metallic material for the first and/or second electrode layer.

According to the invention, the material of the semiconductor layer is not restricted, provided that it can be used to convert solar energy to electrical energy in a thin-film solar module. The primary material of the semiconductor layer may be not only amorphous silicon hydride, but also amorphous silicon, polycrystalline or microcrystalline silicon, or a combination thereof. In addition, silicon can be replaced by silicon carbide, silicon-germanium, germanium, a III-V compound (for example GaAs, InP and alloys and compounds derived therefrom), a II-VI compound (for example CdTe or CuInSe₂), or a I-III-VI compound, or the like. Furthermore, it can be replaced by a combination of these compounds.

In general, a plurality of solar cells are connected in series or in parallel on a single substrate in the thin-film solar module according to the invention. According to the invention, the surface of the thin-film solar module is not restricted.

The subject matter of the invention is also a method for production of a thin-film solar module according to the present invention, comprising the following steps:

(a1) formation of a first electrode layer on a substrate;

(b1) production of a first non-linear recess in the first electrode layer;

(c1) formation of a semiconductor layer on the first electrode layer;

(d1) production of a third recess in the semiconductor layer;

(e1) formation of a second electrode layer which fills the third recess;

(f1) production of a second non-linear recess in the semiconductor layer and in the second electrode layer; and

(g1) production of a fourth recess through the first electrode, the semiconductor layer and the second electrode layer between at least two contact areas which are in the form of islands.

In the method according to the invention, a first transparent electrode layer is preferably formed on the substrate in step (a1).

Furthermore, it is preferable for a semiconductor layer which fills the first non-linear recess to be formed on the first electrode layer in step (c1).

Preferably, a laser is used for production of the first, second, third and/or fourth recess in the method according to the invention.

In general, a desired thin-film solar module is produced by repeatedly depositing individual layers by means of a suitable deposition technique, such as a CVD technique, sputtering technique, or the like, and is structured, for example, by etching or laser radiation.

The thin-film solar module according to the invention and the method for its production have numerous advantages. The thin-film solar module according to the invention is of simple design and can be produced in a simple and therefore economic manner. Because a considerably greater proportion of the surface area can be utilized for conversion of solar energy to electrical energy, the thin-film solar module according to the present invention has a significantly improved efficiency. Furthermore, the present invention makes it possible to produce thin-film solar modules for which the requirements for the accuracy of the positions of the recesses are reduced.

### BRIEF DESCRIPTION OF THE DRAWINGS

The present invention will be explained in more detail in the following text with reference to one preferred embodiment of a thin-film solar module according to the invention, which is illustrated in FIGS. 1 and 2 and is not intended to be restrictive.

FIG. 1 schematically illustrates a plan view of a thin-film solar module according to the invention.

FIG. 2 schematically illustrates a cross section through the thin-film solar module shown in FIG. 1.

### DETAILED DESCRIPTION

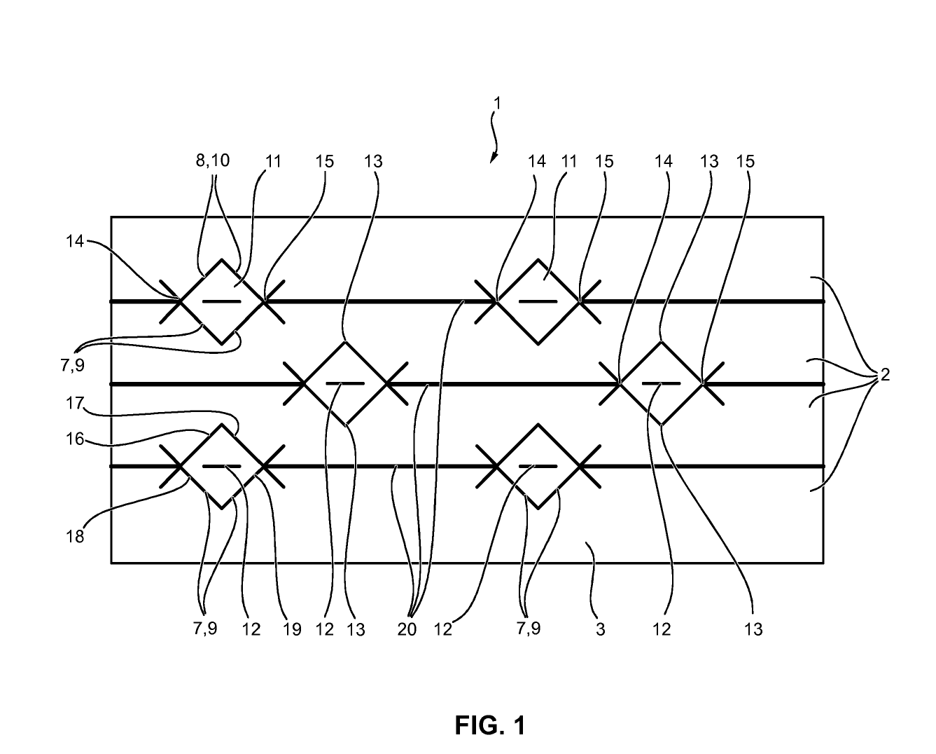

FIG. 1 illustrates a thin-film solar module 1 having a plurality of series-connected solar cells 2. The thin-film solar module 1 has a number of contact areas 11 which are in the form of islands and in each of which two solar cells 2 are connected to one another. The contact areas which are in the form of islands extend—although this cannot be seen in any more detail in FIG. 1—in a direction vertical with respect to a substrate over the layers substrate 3 (for example a glass substrate), first electrode layer, semiconductor layer, and second electrode layer. In a direction parallel to the substrate 3, the contact area 11 which is in the form of an island is bounded by a first projection 9 of a non-linear recess, which is not shown here, in the first electrode layer, and a second projection 10 of a second non-linear recess, which is not shown here, in the semiconductor layer. A third recess 12 is located within the contact area 11, which is in the form of an island, in the semiconductor layer, which is not shown in any more detail here, and this third recess 12 is filled with an electrically conductive material. In the embodiment shown here, a fourth recess 20 extends linearly between projection points 14 and 15 of adjacent contact areas 11 which are in the form of islands.

In the contact areas which are in the form of islands and are shown here, the first non-linear recess 7 and/or the second non-linear recess 8 consist/consists of two linear areas 16, 17, 18, 19 which intersect at a recess intersection point 13. The linear areas which intersect at a recess intersection point 13 in this case extend only slightly behind the recess intersection point 13.

The contact areas which are in the form of islands as shown in FIG. 1 illustrate that part of the surface of a thin-film solar module which is not available for conversion of solar energy to electrical energy, the so-called “dead area”. FIG. 1 illustrates that the present invention makes it possible to achieve a considerable reduction in the dead area (“dead area reduction”).

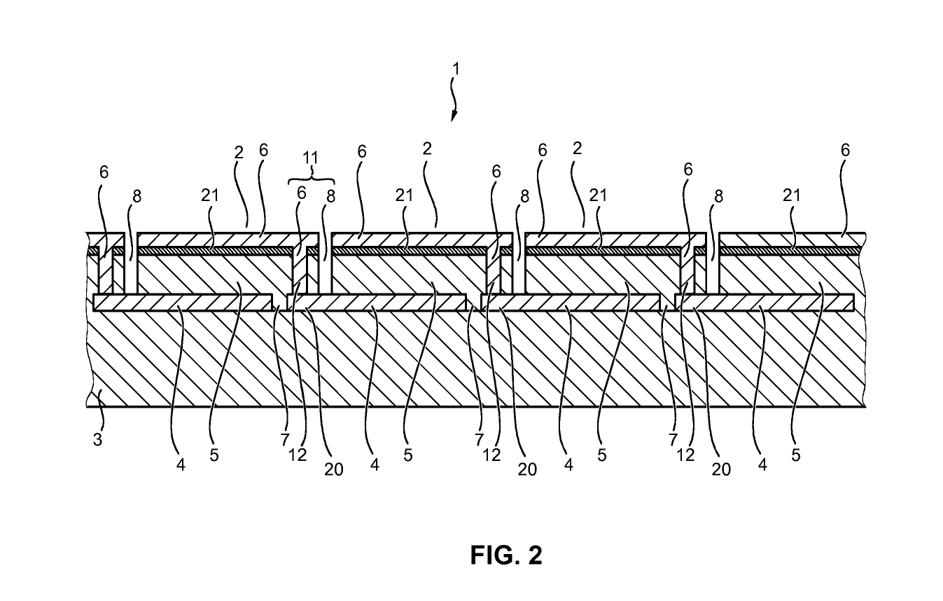

FIG. 2 schematically illustrates a cross section through the thin-film solar module shown in FIG. 1, in the direction of a recess 20. The thin-film solar module 1 contains a plurality of series-connected solar cells 2, two of which are in each case connected to one another in contact areas 11. The island structure of the contact areas 11 cannot be seen in this cross-sectional view. The contact areas 11, which are in the form of islands, extend in a direction which is vertical with respect to a substrate 3 over the substrate 3, a first electrode layer 4, a semiconductor layer 5 and a second electrode layer 6. In a direction parallel to the substrate 3, the contact area 11, which is in the form of an island, is bounded by a first projection, which is not shown here, of a first non-linear recess 7 in the first electrode layer 4 and a second projection, which is likewise not shown here, of a second non-linear recess 8 in the semiconductor layer 5. A third recess 12 is located in the semiconductor layer 5 within the contact area 11 which is in the form of an island, and this third recess 12 is filled with an electrically conductive material. In the embodiment shown in FIG. 2, a fourth recess 20 extends linearly between projection points, which cannot be seen in this illustration, of adjacent contact areas which are in the form of islands. In the cross-sectional view shown in FIG. 2, the fourth recess 20 is located in the same direction as the third recess 12.

Therefore, the structuring results in a plurality of semiconductor layers 5 being arranged on a plurality of first electrode layers 4 in the thin-film solar module 1, which are subdivided on the substrate 3 into a plurality of areas such that each of the semiconductor layers 5 is formed on two adjacent first electrode layers 4 and has a first non-linear recess 7 on one of the first electrode layers 4. In the embodiment illustrated in FIG. 2, a third electrically conductive layer 21 is formed in one area, with the exception of the first non-linear recess 7 on each of the semiconductor layers 5. However, the third electrically conductive layer 21 can also be omitted.

In the embodiment shown in FIG. 2, a second electrode layer 6 is arranged on each of the third electrically conductive layers 21 such that the second electrode layer 6 is electrically connected to one of the two first electrode layers 4 through the first non-linear recess 7, thus forming an area, which is inserted between the second electrode layer 6 and the other first electrode layer 4, as a solar cell 2.

The thin-film solar module as described above can be produced according to the present invention by a preferred method which will be described in more detail in the following text.

A transparent electrically conductive layer, which is produced from a transparent electrically conductive material such as SnO₂, ZnO or ITO, is deposited as the first electrode layer 4 on the substrate 3 (glass substrate 3). The first electrode layer 4 is then melted in order to create a plurality of areas for electrically generating by means of a laser scribing technique, using a non-linearly guided laser. This results in a plurality of first non-linear recesses 7 being formed. In the embodiment shown here, the laser was guided non-linearly by first of all guiding the laser linearly in a first direction and then in a second direction, which differs from the first direction. In the thin-film solar module 1, the surface resistance of the first electrode layer 4 has a value, for example, in the range from 5 to 30 ohms. The first electrode layer 4 is then cleaned, in order to remove those components of the first electrode layer which were melted by the laser scribing.

An amorphous silicon-hydride layer with a pin structure is then deposited as the semiconductor layer 5, for example using a plasma-CVD technique, on the entire surface of the first electrode layers 4, which are formed to correspond to the electricity generating areas.

By way of example, the amorphous silicon-hydride layer can be produced by placing the substrate 3 in a hard-vacuum chamber at a pressure of 10⁻⁵ Torr (approximately 1.33×10⁻³ Pa) or less, and then introducing silane (SiH₄), diborane (B₂H₆) and methane as film formation gases at a substrate temperature of 140 to 200° C. By way of example, the reaction pressure is set to 1.0 Torr, and p-conductive amorphous silicon-hydride-carbide is deposited with a layer thickness of 5 to 20 nm by RF discharge. After this, only silane is introduced into the chamber, the reaction pressure is set to 0.2 to 0.7 Torr, and i-conductive amorphous silicon hydride is deposited with a layer thickness of 300 nm, by RF discharge. In addition, silane (SiH₄), phosphine (PH₃) and hydrogen H₂ are introduced into the chamber, in order to produce a thin film composed of n-conductive microcrystalline silicon. The reaction pressure is set to about 1.0 Torr, and n-conductive microcrystalline silicon is deposited with a thickness of 10 to 20 nm by RF discharge.

A third electrically conductive layer 21 is then deposited onto the semiconductor layer or layers 5 by means of a sputtering technique, without carrying out a previous cleaning process. In particular, the substrate 3 onto which the semiconductor layer 5 is deposited is passed into a sputtering chamber in which a hard vacuum is set with a maximum pressure of 1×10⁻⁶ Torr. Argon (Ar) is introduced as the sputtering gas into the sputtering chamber, following which ZnO doped with aluminum oxide Al₂O₃ is deposited with a thickness of 80 to 100 nm at a pressure of 1 to 5×10⁻³ Torr, by RF discharge.

The semiconductor layer 5 and the third electrically conductive layer 21 are then fused and third recesses 12 produced by a laser scribing technique simultaneously within the contact area 11, which is in the form of an island, in order in this way to produce a plurality of third recesses 12 adjacent to the already formed first non-linear recesses 7 in the first electrode layer 3. After a cleaning process has been carried out on the third recesses 12 in order to remove components which have been melted and separated by the laser scribing process, a metal such as Al, Ag, Cr or the like is then deposited onto the third electrically conductive layers 21, as the second electrode layer 6, by means of a sputtering technique or a vacuum-vapor deposition technique, as already described.

Finally, the first electrode layer 4, the second electrode layer 6, the third electrically conductive layer 21 and the semiconductor layer 4 (in this case an n-conductive microcrystalline silicon layer) are removed between two contact areas 11 by a laser scribing technique, thus forming fourth recesses 20 which, in the cross-sectional view shown in FIG. 2, are located above the third recesses 12.

In the plan view shown in FIG. 1, the fourth recesses 20 extend between two projection points 14, 15 of adjacent contact areas 11 which are in the form of islands. The second electrode layer 6 is in this way subdivided into a plurality of electricity generating areas. This results in the end in a plurality of solar cells 2 on the substrate 3, which each consist of an area inserted between the first electrode layer 4 and the second electrode layer 6, and are connected in series with one another.

The solar cells 2 are then cleaned in order to remove the residues which have been melted and separated by laser scribing. A suitable passivation layer, for example composed of epoxy resin, may be applied to the thin-film solar module.

1. A thin-film solar module which contains a plurality of interconnected solar cells, comprising the following layers in the stated sequence:
(a) a substrate;
(b) a first electrode layer;
(c) a semiconductor layer; and
(d) a second electrode layer;
wherein:
at least one first non-linear recess is arranged in the first electrode layer, and a second non-linear recess is arranged in the second electrode layer and in the semiconductor layer, with a first projection of the first non-linear recess onto the substrate and a second projection of the second non-linear recess onto the substrate intersecting or touching at least two projection points,
the thin-film solar module has at least one contact area which is in the form of an island, extends over the layers (a) to (d) in a direction which is vertical with respect to the substrate and is bounded in a direction parallel to the substrate by the first projection and the second projection, and with a third recess being located in the semiconductor layer within the at least one contact area which is in the form of an island, which third recess is filled with an electrically conductive material, and with a fourth recess extending through the first electrode layer, the semiconductor layer and the second electrode layer between at least two contact areas of the at least one contact layer which are in the form of islands.

2. The thin-film solar module as claimed in claim 1, wherein the first projection and the second projection intersect or touch at two and only two projection points.

3. The thin-film solar module as claimed in claim 1, wherein the first non-linear recess and/or the second non-linear recess consist/consists of two linear areas which intersect or touch at a recess intersection point.

4. The thin-film solar module as claimed in claim 1, wherein the at least one contact area has an area in the range from 0.01 to 3 mm² in a direction parallel to the substrate.

5. The thin-film solar module as claimed in claim 1, wherein the fourth recess is arranged between two projection points of adjacent contact areas which are in the form of islands.

6. The thin-film solar module as claimed in claim 1, wherein said fourth recess comprises a first fourth recess of a plurality of fourth recesses arranged parallel to one another.

7. The thin-film solar module as claimed in claim 1, wherein the fourth recess is linear.

8. The thin-film solar module as claimed in claim 7, wherein the fourth recess connects the projection points of two adjacent contact areas which are in the form of islands.

9. The thin-film solar module as claimed in claim 1, further comprising a third electrically conductive layer, which is different from the second electrode layer, and is arranged between the semiconductor layer and the second electrode layer.

10. The thin-film solar module as claimed in claim 1, wherein the first electrode layer is transparent.

11. A method for production of a thin-film solar module as claimed in claim 1, comprising the following steps:
(a1) formation of a first electrode layer on a substrate;
(b1) production of a first non-linear recess in the first electrode layer;
(c1) formation of a semiconductor layer on the first electrode layer;
(d1) production of a third recess in the semiconductor layer;
(e1) formation of a second electrode layer which fills the third recess;
(f1) production of a second non-linear recess in the semiconductor layer and in the second electrode layer; and
(g1) production of a fourth recess through the first electrode, the semiconductor layer and the second electrode layer between at least two contact areas which are in the form of islands.

12. The method as claimed in claim 11, further comprising a first transparent electrode layer formed on the substrate in step (a1).

13. The method as claimed in claim 11, further comprising a semiconductor layer filling the first non-linear recess and formed on the first electrode layer in step (c1).

14. The method as claimed in claim 11, further comprising a laser being used for production of the first, second, third and/or fourth recess.

15. The thin-film solar module as claimed in claim 2, wherein the first non-linear recess and/or the second non-linear recess consist/consists of two linear areas which intersect or touch at a recess intersection point.

16. The thin-film solar module as claimed in claim 2, wherein the contact area has an area in the range from 0.01 to 3 mm² in a direction parallel to the substrate.

17. The thin-film solar module as claimed in claim 2, wherein the fourth recess is arranged between two projection points of adjacent contact areas which are in the form of islands.

18. The thin-film solar module as claimed in claim 2, wherein said fourth recess comprises a first fourth recess of a plurality of fourth recesses arranged parallel to one another.

19. The thin-film solar module as claimed in claim 2, wherein the fourth recess is linear.

20. The thin-film solar module as claimed in claim 3, wherein the fourth recess is linear.
